(19) United States
(12) Patent Application Publication
(10) Pub. No.: US 2024/0213056 A1
(43) Pub. Date: Jun. 27, 2024

(54) RECONFIGURABLE MAINFRAME WITH REPLACEABLE INTERFACE PLATE HAVING REPLACEABLE CHAMBER PORTS

(71) Applicant: Applied Materials, Inc., Santa Clara, CA (US)

(72) Inventors: Angela Rose Sico, Round Rock, TX (US); Travis Morey, Austin, TX (US); Michael C. Kuchar, Georgetown, TX (US); Sushant S. Koshti, Sunnyvale, CA (US)

(21) Appl. No.: 18/389,664

(22) Filed: Dec. 19, 2023

Related U.S. Application Data
(60) Provisional application No. 63/477,143, filed on Dec. 23, 2022.

(51) Int. Cl. H01L 21/67; H01L 21/677; H01L 21/687

(52) U.S. Cl. CPC H01L 21/67167; H01L 21/67196; H01L 21/67742; H01L 21/68707

(57) ABSTRACT

A mainframe of a device fabrication system includes a base, a plurality of facets on the base, and a lid over the plurality of facets. A first facet of the plurality of facets includes a frame. The base, the lid and the plurality of facets together define an interior volume that includes a robot arm. A first replaceable interface plate is attached to the first frame of the first facet. The first replaceable interface plate includes a plurality of replaceable chamber ports. A first replaceable camber port of the plurality of replaceable chamber ports is configured to provide access for the robot arm to a first process chamber. A second replaceable chamber port of the plurality of replaceable chamber ports is configured to provide access for the robot arm to a second process chamber.

### RELATED APPLICATIONS

This patent application claims the benefit under 35 U.S.C. § 119(e) of U.S. Provisional Application No. 63/477,143, filed Dec. 23, 2022, which is incorporated by reference herein.

### FIELD OF THE DISCLOSURE

Embodiments of the present disclosure relate generally to electronic device manufacturing systems, and more particularly to a reconfigurable mainframe of an electronic device manufacturing system that includes a replaceable interface plate having one or more replaceable chamber ports. Embodiments also relate to replaceable interface plates for mainframes that have attached replaceable chamber ports, and to mainframes with integrated lids.

### BACKGROUND OF THE DISCLOSURE

Conventional electronic device manufacturing systems (also referred to as device fabrication systems) may include a mainframe around which multiple process chambers and load lock chambers are arranged. The mainframe may have a number of side walls (commonly referred to as “facets”) to which process chambers and/or load lock chambers are coupled. The facets of conventional mainframes are machined to have a pre-arranged configuration with chamber ports that have predetermined sizes, positions, etc. Once a conventional mainframe is manufactured, the type, size, arrangement and location of chamber ports are fixed for that mainframe. If an owner of the mainframe wants a new configuration, then a new mainframe having the new configuration is then purchased.

### SUMMARY OF THE DISCLOSURE

According to a first aspect of the disclosure, a mainframe of a device fabrication system includes a base, a plurality of facets on the base, and a lid over the plurality of facets. A first facet of the plurality of facets includes a first frame. The base, the lid and the plurality of facets together define an interior volume that includes one or more robot arms. A first replaceable interface plate is attached to the first frame of the first facet. The first replaceable interface plate includes a plurality of replaceable chamber ports. A first replaceable chamber port of the plurality of replaceable chamber ports is configured to couple to, and to provide access for the robot arm to, a first process chamber. A second replaceable chamber port of the plurality of replaceable chamber ports is configured to couple to, and to provide access for the robot arm to, a second process chamber.

According to a second aspect of the disclosure, a replaceable interface plate for attachment to a facet of a mainframe comprises a plurality of openings, each opening of the plurality of openings configured to receive a removable chamber port (also referred to as a replaceable chamber port). The replaceable interface plate further comprises a first removable chamber port coupled to the replaceable interface plate at a first opening of the plurality of openings, wherein the first chamber port is configured to couple to a first process chamber. The replaceable interface plate further comprises a second removable chamber port coupled to the replaceable interface plate at a second opening of the plurality of openings, wherein the second chamber port is configured to couple to a second process chamber.

According to a third aspect of the disclosure, a method comprises detaching a first process chamber from a mainframe of a device fabrication system comprising a base, a plurality of facets on the base, and a first replaceable interface plate attached to a first frame of a first facet of the plurality of facets, the first replaceable interface plate comprising a plurality of replaceable chamber ports, wherein detaching the first process chamber from the mainframe comprises detaching the first process chamber from a first replaceable chamber port coupled to the first replaceable interface plate. The method further comprises detaching the first replaceable chamber port from a first opening of the first replaceable interface plate, wherein the first replaceable chamber port is configured to couple to the first process chamber. The method further comprises attaching a second replaceable chamber port to the first opening of the first replaceable interface plate, wherein the second replaceable chamber port is configured to couple to a second process chamber different from the first process chamber. The method further comprises attaching the second process chamber to the mainframe by attaching the second process chamber to the second replaceable chamber port.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1A illustrates a schematic top view of an electronic device manufacturing system having a reconfigurable mainframe with a first configuration, in accordance with an embodiment of the present disclosure.

FIG. 1B illustrates a schematic top view of an electronic device manufacturing system having a reconfigurable mainframe with a second configuration, in accordance with an embodiment of the present disclosure.

FIG. 1C illustrates a schematic top view of an electronic device manufacturing system having a reconfigurable mainframe with a third configuration, in accordance with an embodiment of the present disclosure.

FIG. 2A illustrates a perspective view of a reconfigurable mainframe, in accordance with an embodiment of the present disclosure.

FIG. 2B illustrates a side view of a first example replaceable interface plate, in accordance with an embodiment of the present disclosure.

FIG. 2C illustrates a side view of a second example replaceable interface plate, in accordance with an embodiment of the present disclosure.

FIG. 2D illustrates a side view of a third example replaceable interface plate, in accordance with an embodiment of the present disclosure.

FIG. 3 depicts a cross sectional side view of a mainframe and an attached replaceable interface plate, taken at a location of a chamber port, in accordance with an embodiment of the present disclosure.

FIG. 4 illustrates a process for assembling a reconfigurable mainframe of an electronic device manufacturing system, in accordance with an embodiment of the present disclosure.

FIG. 5A illustrates a first method for replacing a process chamber of a mainframe, in accordance with an embodiment of the present disclosure.

FIG. 5B illustrates a second method for replacing a process chamber of a mainframe, in accordance with an embodiment of the present disclosure.

FIG. 6 illustrates a schematic isometric view of a reconfigurable mainframe for an electronic device manufacturing system, in accordance with an embodiment of the present disclosure.

FIG. 7A illustrates a replaceable interface plate with replaceable chamber ports for a reconfigurable mainframe of an electronic device manufacturing system, in accordance with an embodiment of the present disclosure.

FIG. 7B illustrates a chamber side of the replaceable interface plate of FIG. 7A with the replaceable chamber ports removed, in accordance with an embodiment of the present disclosure.

FIG. 7C illustrates a mainframe side of the replaceable interface plate of FIG. 7A with the replaceable chamber ports removed, in accordance with an embodiment of the present disclosure.

FIG. 8A illustrates a replaceable chamber port for a replaceable interface plate, in accordance with an embodiment of the present disclosure.

FIG. 8B illustrates top isometric view of a body of the replaceable chamber port of FIG. 8A, in accordance with an embodiment of the present disclosure.

FIG. 8C illustrates bottom isometric view of a body of the replaceable chamber port of FIG. 8A, in accordance with an embodiment of the present disclosure.

### DETAILED DESCRIPTION

Embodiments are directed to a reconfigurable mainframe (also referred to as a transfer chamber) with one or more replaceable interface plates that include one or more replaceable chamber ports. The reconfigurable mainframe includes multiple facets, where at least one of the facets includes a frame configured to accept a replaceable interface plate. In one embodiment, the reconfigurable mainframe includes a frame for each facet of the reconfigurable mainframe. A replaceable interface plate may attach to each of the frames. A lid may be positioned over the frames of the facets, and may be secured to the replaceable interface plates. In embodiments, the lid is an integrated lid that is not separable from the frame of the reconfigurable mainframe. In embodiments, the replaceable interface plates are load bearing, and the frames are not load bearing with respect to a load caused by exposing the mainframe to vacuum. Accordingly, when an interior volume of the mainframe is pumped down to vacuum, vertical (and horizontal) forces are sustained by the replaceable interface plates, but little or no forces are applied to the frames. In some embodiments, the lid includes a first plurality of weight transfer features that protrude from the integrated lid and some or all of the replaceable interface plates include a second plurality of weight transfer features disposed on a top face of the replaceable interface plates. The first plurality of weight transfer features may be configured to interface with the second plurality of weight transfer features to transfer a load from the integrated lid to the replaceable interface plates.

In embodiments, one or more of the replaceable interface plates includes replaceable chamber ports. Accordingly, the reconfigurable mainframe may include nested reconfigurability. If a chamber port location or number of chamber ports is to be modified for the mainframe, then an existing interface plate may be swapped out for a new interface plate having the different number of chamber ports and/or different chamber port locations. However, if a new chamber that uses a different type of chamber port is to be attached to the mainframe, then the replaceable interface plate may not be changed, and instead a replaceable chamber port attached to the replaceable interface plate may instead be removed and replaced with a different replaceable chamber port. This maximizes the flexibility of reconfigurability of the mainframe with minimum cost. Additionally, in embodiments by separating functionality of chamber ports from functionality of interface plates, an amount of material used to manufacture the interface plates may be reduced. For example, to manufacture an interface plate that has an integrated chamber port, a thick aluminum blank may be used to accommodate features of the chamber port and features of a remainder of the interface plate. This may include machining away a large volume of the aluminum blank for regions of the interface plate that are not part of the chamber port. However, by separately manufacturing an interface plate and a chamber port, a much thinner aluminum blank may be started with for the interface plate, thus reducing an amount of waste of materials.

In some embodiments, the mainframe may have a square or rectangular shape. One or more load lock chambers may be coupled to one facet of the mainframe. In one embodiment, the one or more load lock chambers are coupled to a replaceable interface plate on one facet of the mainframe. In one embodiment, additional replaceable interface plates are connected to one or more additional facets of the mainframe, and one or more process chambers are coupled to some or all of the additional replaceable interface plates via one or more replaceable chamber ports attached to the additional replaceable interface plates. The process chambers may perform various substrate processes, and the process chambers coupled to different replaceable interface plates on the facets via the different replaceable chamber ports may be of different size, have different size chamber ports, have different connection types, have different heights, and so on. For example, some chamber ports may include heights that accommodate two end effectors at different pitches. Also, different replaceable interface plates may be configured to couple to the same number or a different number of process and/or load lock chambers. For example, one replaceable interface plate may be configured to couple to a single process chamber of a first size, a second replaceable interface plate may be configured to couple to two process chambers each of a second size different than the first size, and so on.

One or more replaceable chamber ports on each replaceable interface plate may interface each of the load lock and process chambers with the transfer chamber to allow substrates to be transferred there between. Different types of replaceable chamber ports may be attached to the same and/or different replaceable interface plates, where the type of chamber port to be used may be based at least in part on a type of chamber that the replaceable interface plate will attach to. The chamber ports may be sized and positioned on each replaceable interface plate to accommodate the number and size of chambers that may be coupled to each facet, and may be selected based on the type of chambers to be connected to. Electronic device manufacturing systems having such a mainframe may allow a wider variety and more diverse sequences of substrate processes to be performed in a single system, thus improving versatility, capability, and/or efficiency of such electronic device manufacturing systems. In other aspects, methods of assembling an electronic device manufacturing system are provided.

The reconfigurable mainframe and replaceable interface plates with replaceable chamber ports disclosed in embodiments provide multiple advantages over traditional mainframes. A traditional mainframe has a single design that is determined at the time of manufacture. That single design has a fixed number and type of chamber ports with fixed size and fixed position. If at any time it would be advantageous to change a configuration of such a conventional mainframe, the available option is to purchase a new mainframe having the new configuration. In contrast, the reconfigurable mainframe can be reconfigured at any time by manufacturing new replaceable interface plates and/or by manufacturing new chamber ports. If a new configuration would be beneficial, then one or more new replaceable interface plates having the new configuration may be manufactured and/or one or more new chamber ports having the new configuration or type may be used to replace an existing replaceable chamber port. The existing replaceable interface plates may then be removed from the mainframe, and the new replaceable interface plates may be attached to the mainframe. Alternatively, the existing chamber port(s) may be removed from a replaceable interface plate and a new chamber port(s) may be mounted to the replaceable interface plate. Thus, the flexibility of mainframes is significantly improved in embodiments. Furthermore, the useful lifespan of mainframes can be increased because the mainframes can be updated with new replaceable interface plates and/or new chamber ports as new process chambers become available, new slit valve technologies are developed, new local center finding (LCF) technologies are developed (e.g., using light emitting diodes (LEDs), lasers and/or other scanning methods to determine where a wafer resides within a pocket of a robot blade or end effector), and so on. Old replaceable interface plates and/or replaceable chamber ports having out dated slit valve technologies, outdated local center finding technologies, etc. can be swapped out with new replaceable interface plates and/or chamber ports that have new slit valve technologies and/or new local center finding technologies, for example.

As used herein, the singular forms “a,” “an,” and “the” include plural references unless the context clearly indicates otherwise. Thus, for example, reference to “a substrate” includes a single substrate (e.g., a single wafer) as well as a mixture of two or more substrates; and reference to a “process chamber” includes a process chamber as well as a mixture of two or more process chambers, and the like.

As used herein, the term “about” in connection with a measured quantity, refers to the normal variations in that measured quantity, as expected by one of ordinary skill in the art in making the measurement and exercising a level of care of one skilled in the art and the precision of the measuring equipment. In certain embodiments, the term “about” includes the recited number ±10%, such that “about 10” would include from 9 to 11.

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

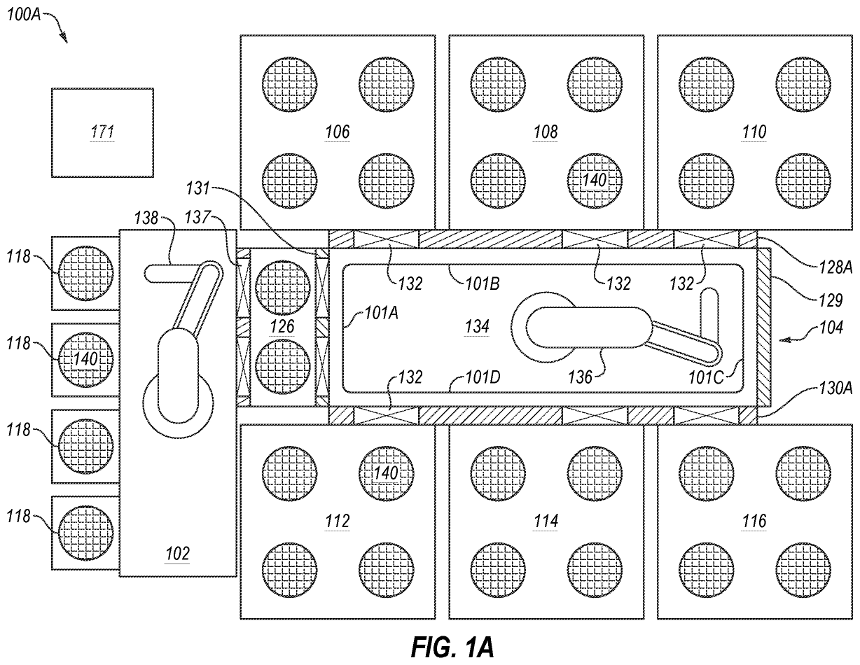

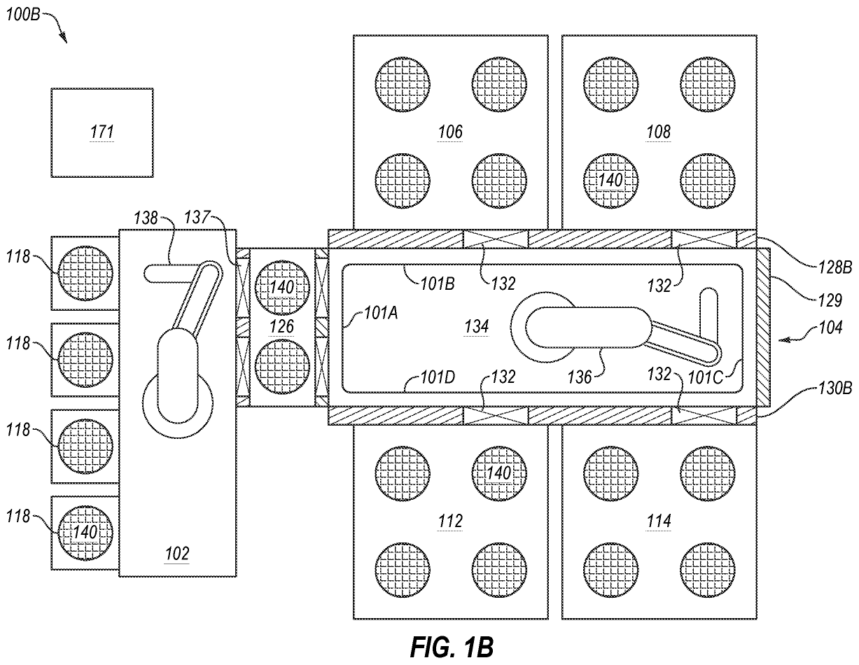

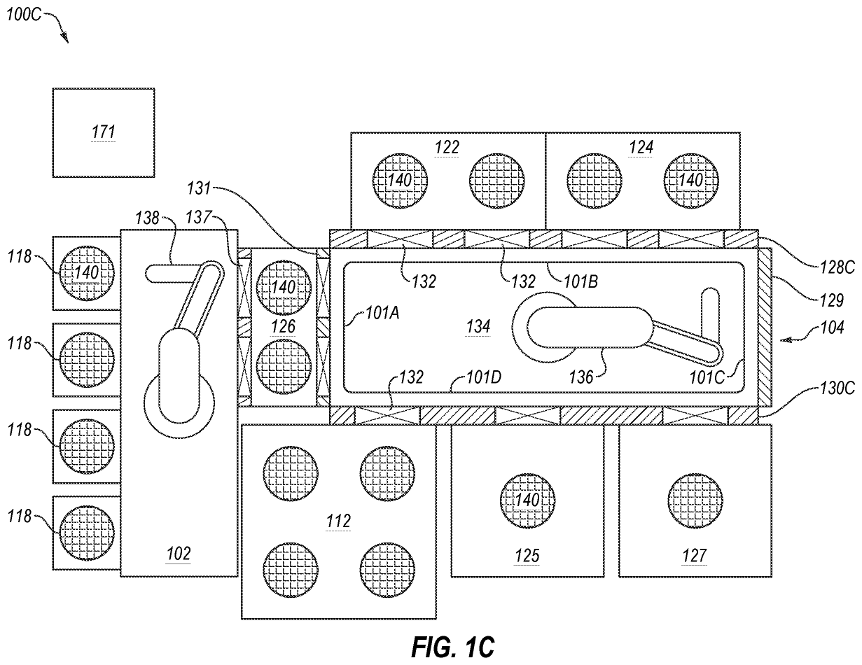

FIGS. 1A-C illustrate schematic top views of an electronic device manufacturing system having a reconfigurable mainframe with one or more replaceable interface plates and/or replaceable chamber ports. FIG. 1A illustrates a schematic top view of a first configuration 100A of the electronic device manufacturing system, in accordance with an embodiment of the present disclosure. FIG. 1B illustrates a schematic top view of a second configuration 100B of the electronic device manufacturing system, in accordance with an embodiment of the present disclosure. FIG. 1C illustrates a schematic top view of a third configuration 100C of the electronic device manufacturing system, in accordance with an embodiment of the present disclosure.

The electronic device manufacturing system is configured to process substrates and may include a mainframe (also referred to as a transfer chamber) 104 having four facets 101A-D. Though four facets 101A-D are illustrated in a rectangular configuration, the mainframe 104 may alternatively have other numbers of facets (e.g., such as 5 facets, 6 facets, 7 facets, 8 facets, etc.) and/or other shapes. The facets may have the same sizes (e.g., the same widths) or different sizes in embodiments. In one embodiment, the mainframe 104 has a rectangular shape, with facets 101A and 101C being approximately parallel to one another, facets 101B and 101D being approximately parallel to one another, and facets 101A and 101C being approximately perpendicular to facets 101B and 101D. In one embodiment, facets 101B and 101D have a first length that is at least two times a second length of facets 101A and 101C. In one embodiment, facets 101B and 101D have a length of about 100-150 inches, and facets 101A and 101C have a length of about 40-60 inches. In one embodiment, the mainframe 104 has a pentagonal shape. In one embodiment, the mainframe includes a first facet having a first length, second and third facets on either side of the first facet, each having a second length that is greater than the first length, and a fourth and fifth facet connected to the second and third facet, respectively, each having a third length that is greater than or equal to the first length and less than the second length.

Mainframe 104 may include an interior volume 134, wherein facets 101A-D may define the side walls of the interior volume 134. The mainframe 104 may additionally include a base (not shown) and a lid (not shown). The facets 101A-D, base and lid may together define the interior volume 134. In embodiments, the lid is an integrated lid that is not removable. One or more robot arms (also referred to as a robot assembly) 136 may be disposed within the interior volume 134 of the mainframe 104. While a single robot arm 136 is shown, in some embodiments the transfer chamber includes dual robot arms (e.g., a first robot arm and a second robot arm). The interior volume 134 may typically be under vacuum during operation of the mainframe 104.

Each of facets 101A-D may comprise a frame and may have attached thereto a replaceable interface plate. Alternatively, a subset of the facets 101A-D may comprise frames with replaceable interface plates attached thereto. Other facets may be manufactured in a conventional manner with built-in sidewalls having a fixed configuration. For each facet having a frame rather than a fixed configuration, a replaceable interface plate may be attached to the frame of the facet, and may form the sidewall of the facet. In embodiments, each facet is configured to receive at most a single replaceable interface plate. At any time an existing replaceable interface plate attached to a facet may be removed, and a new replaceable interface plate having a different design may be attached to that facet. Thus, the mainframe 104 is a reconfigurable mainframe with a flexible design. Additionally, one or more of the replaceable interface plates includes one or more replaceable chamber ports, further increasing a design flexibility for the mainframe.

In FIG. 1A, a replaceable interface plate 128A is attached to facet 101B, a replaceable interface plate 129 is attached to facet 101C, a replaceable interface plate 130A is attached to facet 101D, and a replaceable interface plate 131 is attached to facet 101A. Replaceable interface plate 128A has three attached replaceable chamber ports 132. Each replaceable chamber port 132 may be configured to attach to a specific type of chamber (e.g., a specific type of process chamber or load lock chamber) and allow a horizontally-oriented substrate 140 to pass there through (e.g., into and out of the attached process chamber). Substrate 140 may be a wafer (e.g., a semiconductor wafer or a non-semiconductor device substrate), glass plate or panel, and/or other workpiece used to make electronic devices or circuit components.

Each replaceable interface plate 128A, 130A may include an opening for each chamber port 132. The opening may be an elongated slot or slit formed in a side wall of a replaceable interface plate 128A, 130A. A replaceable chamber port 132 may be attached to the replaceable interface plate 128A, 130A at each opening and may include, e.g., a slit valve or other suitable device for opening and closing a chamber port 132 and/or a local center finder (LCF) suitable for determining a position of a substrate 140 transferred through a chamber port 132. Replaceable chamber port 132 may additionally or alternatively include other sensors and/or metrology devices for measuring properties of substrates passed through chamber port 132. For example, replaceable chamber port 132 may include a contactless temperature sensor (e.g., an infrared temperature sensor), a particle detection sensor, a film thickness sensor, and so on. Slit valves may be of any suitable conventional construction, such as, e.g., L-motion slit valves. Other suitable devices may also be used for opening and closing chamber ports 132. Replaceable chamber ports 132 may include single gates or dual gates (e.g., with a first gate on an interior of the replaceable interface plate at a chamber port and a second gate on an exterior of the replaceable interface plate at the chamber port) in embodiments.

Three process chambers 106, 108, 110 are attached to the replaceable interface plate 128A. Each of the process chambers 106-110 lines up with a replaceable chamber port 132 mounted to the replaceable interface plate 128A.

Replaceable interface plate 130A has three replaceable chamber ports 132 attached thereto. Three process chambers 112, 114, 116 are attached to the replaceable interface plate 130A. Each of the process chambers 112-116 lines up with a replaceable chamber port 132 mounted to the replaceable interface plate 130A.

Replaceable interface plate 129 is a solid plate that has no openings. Replaceable interface plate 131 includes attached replaceable chamber ports 132. Replaceable interface plate 131 is coupled to one or more load lock chamber 126 (which may include two side-by-side load lock chambers, for example). In one embodiment, the replaceable interface plate 131 includes one or more integrated chamber ports that couple to the load lock chambers 126.

Load lock chambers 126 may each be a batch-type or single substrate-type of load lock chamber. In some embodiments, load lock chamber 126 may be a stacked load lock chamber. For example, load lock chamber 126 may be a double-stacked load lock chamber, a triple-stacked load lock chamber, a load lock chamber with four or more stacked load locks (e.g., a quad load lock chamber), and so on. Alternatively, load lock chamber 126 may be a single volume load lock chamber. Each of load lock chambers 126 may be configured to couple to a respective chamber port 132. For example, a stacked load lock chamber 126, which may have two separate substrate volumes, may have two vertically-aligned ports corresponding respectively to vertically aligned chamber ports 132. A triple-stacked load lock chamber, which may have three separate substrate volumes, may have three vertically-aligned ports corresponding to vertically aligned chamber ports. Single volume load lock chambers may have a single port corresponding to a single chamber port 132. Any one or more of load lock chambers 126 may be a stacked load lock chamber, a triple-stacked load lock chamber, and/or a single volume load lock chamber. Also, in some embodiments, any one or more of load lock chambers 126 may be a process-capable chamber. That is, any one or more of load lock chambers 126, or any one of the volumes located therein, may be capable of performing a substrate pre-heating process, an abatement process, a cooling process, and/or another treatment process. Each load lock chamber 126 may include additional ports 137 that are configured to couple to a factory interface 102 (also known as an equipment front end module (EFEM)).

Mainframe 104, process chambers 106-116, and/or load lock chambers 126 may each operate at a vacuum pressure. Process chambers 106-116 may each perform a same or different process on a substrate 140 including, e.g., deposition, oxidation, nitridation, etching, polishing, cleaning, lithography, inspection, or the like. Other processes may also be performed therein.

Mainframe 104 may also include a robot assembly 136 in the interior volume 134. Robot assembly 136 may be configured to transfer one or more substrates 140 to and from each process chamber 106-116 and load lock chamber 126. Robot assembly 136 may be configured to transfer substrates 140 from any one chamber directly to any other chamber attached to mainframe 104. In some embodiments, substrates 140 may be transferred by robot assembly 136 in any sequence or direction. In some embodiments, robot assembly 136 may have dual robot arms and/or transport blades (or more transport blades, also referred to as end effectors) each independently projectable and retractable to and from any chamber attached to mainframe 104, thus increasing system throughput by enabling concurrent substrate transfers. In some embodiments, robot assembly 136 may have a single transport blade. In some embodiments, robot assembly 136 may include one or more SCARA (selective compliance articulated robot arm) robots. Alternatively, robot assembly 136 may be any suitable mechanism for transferring substrates between the chambers attached to mainframe 104, such as a linear robot or a non-linear robot.

Load lock chambers 126 may be coupled to factory interface 102, which may be coupled to one or more FOUPs (front opening unified pods) 118 or other substrate carriers. One or more load lock chambers 126 may provide a first vacuum interface between factory interface 102 and the transfer chamber 126. In some embodiments, each of load lock chambers 126 may increase substrate throughput by alternately communicating with mainframe (transfer chamber) 104 and factory interface 102. That is, while one load lock chamber 126, or any one volume of a stacked or triple-stacked load lock chamber, communicates with transfer chamber 104, the other load lock chambers 126, or the other volumes of a stacked or triple-stacked load lock chamber, may communicate with factory interface 102. Substrate transfers between factory interface 102, load lock chambers 126, and transfer chamber 104 may be made in any other suitable manner.

FOUPs 118 may each be a container having a stationary cassette therein for holding multiple substrates. FOUPs 118 may each have a front opening interface configured to be used with factory interface 102. Factory interface 102 may have a buffer chamber (not shown) and one or more robot assemblies 138 configured to transfer substrates 140 via linear, rotational, and/or vertical movement between FOUPs 118 and load lock chambers 126. Substrates may be transferred between FOUPs 118 and load lock chambers 126 in any sequence or direction. Load lock chambers 126 may each be a batch-type or single substrate-type of load lock chamber.

A controller 171 may control robot assembly 138, robot assembly 136 and/or the operation of the electronic device manufacturing system. The controller 171 may control the processing and transferring of substrates 140 in and through the electronic device manufacturing system. Controller 171 may be, e.g., a general purpose computer and/or may include a microprocessor or other suitable CPU (central processing unit), a memory for storing software routines that control electronic device manufacturing system, input/output peripherals, and support circuits (such as, e.g., power supplies, clock circuits, circuits for driving robot assembly 138, 136, a cache, and/or the like). Controller 171 may be programmed to, e.g., process one or more substrates sequentially through each of the process chambers attached to mainframe 104. In other embodiments, controller 171 may be programmed to process a substrate in any order through the process chambers. In still other embodiments, controller 171 may be programmed to skip and/or repeat processing of one or more substrates in one or more process chambers. Controller 171 may alternatively be programmed to process one or more substrates in the electronic device manufacturing system in any suitable manner.

The electronic device manufacturing system may have other suitable numbers of FOUPs 118 and/or load lock chambers 126 than those shown. In some embodiments, the number of load lock chambers coupled to facet 101A may be independent of the number of process chambers coupled to any one of facets 101B-D. For example, the number of load lock chambers may be different than the highest number of process chambers coupled to a facet. Also, in some embodiments, up to four process chambers may be coupled to a single facet, or more than four process chambers may be coupled to a single facet, depending on the size of mainframe 104 relative to the size(s) of the four process chambers.

FIG. 1B illustrates the same FOUPs 118, factory interface 102, load locks 126 and mainframe 104 as shown in FIG. 1A. However, in FIG. 1B replaceable interface plate 128A has been removed from facet 101B and replaceable interface plate 128B has been attached to facet 101B. Similarly, replaceable interface plate 130A has been removed from face 101D and replaceable interface plate 130B has been attached to facet 101D. Replaceable interface plate 128B has two attached replaceable chamber ports 132, as opposed to the three replaceable chamber ports 132 of replaceable interface plate 128A. Similarly, replaceable interface plate 130B has two replaceable chamber ports 132, as opposed to the three replaceable chamber ports 132 of replaceable interface plate 130A. Accordingly, in the second configuration 100B, process chambers 106, 108, 112 and 114 have been repositioned, and process chambers 110 and 116 have been removed.

FIG. 1C illustrates the same FOUPs 118, factory interface 102, load locks 126 and mainframe 104 as shown in FIGS. 1A-B. However, in FIG. 1C replaceable interface plate 128A has been removed from facet 101B and replaceable interface plate 128C has been attached to facet 101B. Similarly, replaceable interface plate 130A has been removed from face 101D and replaceable interface plate 130C has been attached to facet 101D. Replaceable interface plate 128C has four replaceable chamber ports 132, as opposed to the three replaceable chamber ports 132 of replaceable interface plate 128A. Replaceable interface plate 130C has three replaceable chamber ports 132, but they are in different positions than the three replaceable chamber ports 132 of replaceable interface plate 130A. In the third configuration 100C, process chamber 112 is in the same position, but process chambers 106, 108, 110, 114 and 116 have been removed and replaced with process chambers 122, 124, 125 and 127.

As shown, any type of process chamber may connect to a facet of the mainframe 104 via a replaceable interface plate. Though not shown, any of the replaceable chamber ports may be removed from one of the replaceable interface plates and replaced with a different replaceable chamber port, without changing the replaceable interface plate itself, providing still greater flexibility in configuration of the electronics processing system. Some examples of process chambers include quad process chambers (e.g., including process chambers 106-116), single process chambers (e.g., including process chambers 125, 127) and twin process chambers (e.g., including process chambers 122, 124).

Each of the replaceable chamber ports 132 may share a size and/or shape or be of a different size and/or shape. Each replaceable interface plate 128A-C, 130A-C, 129, 131 may include the same or a different number of replaceable chamber ports 132, which may be of similar or different sizes and/or shapes. For example, some replaceable chamber ports may have slit value with a first width (e.g., to receive 200 mm wafers), some replaceable chamber ports may have a slit valve with a second width (e.g., to receive 300 mm wafers), and some replaceable chamber ports may have a slit valve with a third width. The width of the slit valve for each replaceable chamber port 132 is at least wide enough to allow a substrate 140 to pass there through. The different sizes of replaceable chamber ports may allow robot assembly 136 to reach different areas within a chamber coupled to one of facets 101A-D. In some embodiments wherein replaceable interface plate has two or more replaceable chamber ports, the replaceable chamber ports may not be laterally centered in the substrate interface plate and/or equidistantly spaced from each other. In some embodiments wherein a replaceable interface plate has a single replaceable chamber port, that replaceable chamber port may be laterally centered in the facet or offset.

In an example, the replaceable interface plate 128A is interchangeable with a plurality of additional replaceable interface plates that have a) a different number of attached replaceable chamber ports than the replaceable interface plate 128A, b) different locations of one or more replaceable chamber ports as compared to the plurality of replaceable chamber ports in the replaceable interface plate 128A, c) different sizes of one or more replaceable chamber ports as compared to the plurality of replaceable chamber ports in the replaceable interface plate 128A, d) a different type of slit valves in the replaceable chamber ports than those of the replaceable interface plate 128A, and/or e) a different type of local center finder than the replaceable interface plate 128A.

Each of the replaceable interface plates may have various numbers, sizes, and/or combinations of openings for attaching replaceable chamber ports, provided the width of a facet is suitable for accommodating those numbers, sizes, and/or combinations of replaceable chamber ports. For example, in some embodiments, a replaceable interface plate may have one attached replaceable chamber port 132 instead of three replaceable chamber ports 132. In other embodiments, one replaceable interface plate may have one replaceable chamber port 132 of a first width and one replaceable chamber port 132 of a second width, while another replaceable interface plate may have one replaceable chamber port of the first width and one replaceable chamber port of a third width. Various combinations of replaceable chamber ports may be possible provided the facet has a suitable width. This allows a mainframe 104 to be customized for coupling to specific types and numbers of process and load lock chambers. In an example, the first width may be about 1.2 meters, the second width may be about 2.4 meters, and the third width may be about 800 mm.

In some embodiments, two electronic device manufacturing systems may be clustered. That is, one facet of each mainframe 104, such as, e.g., a facet 101C of a first mainframe and a facet of a second mainframe 202, may each include replaceable interface plates that enable the two mainframes to be coupled (e.g., with one or more load lock interposed between the two mainframes). Alternatively, a single interface plate may couple to a first mainframe on a first side and to a second mainframe on an opposite side. Such an interface plate may be referred to as a pass-through interface plate. The mainframes may be coupled in a manner that provides a pass-through chamber for transferring substrates between the two mainframes. This may further enhance the versatility, capability, and/or efficiency of such electronic device manufacturing systems.

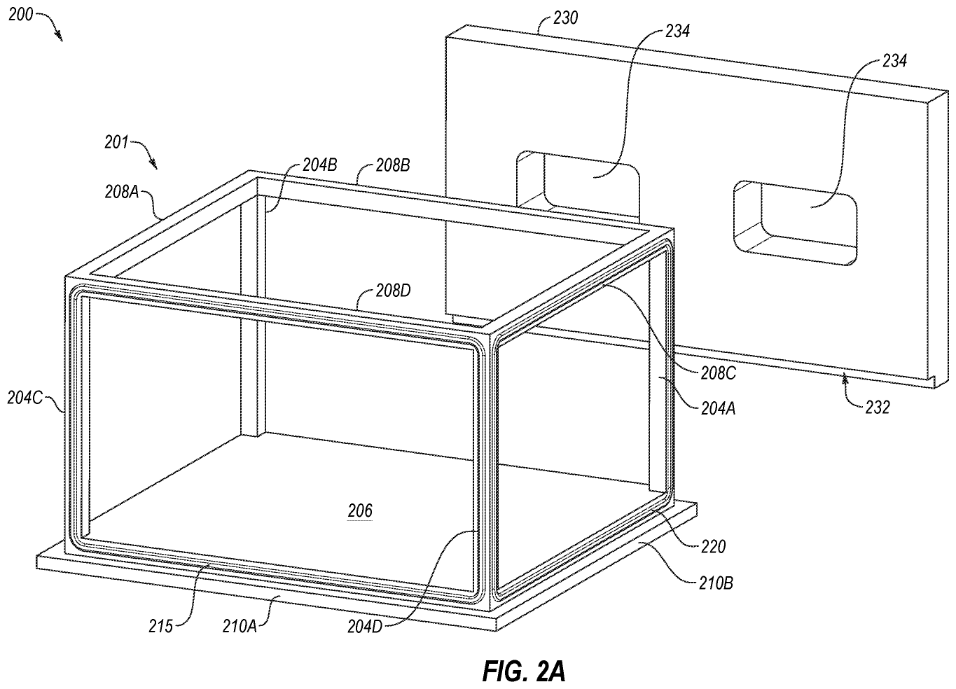

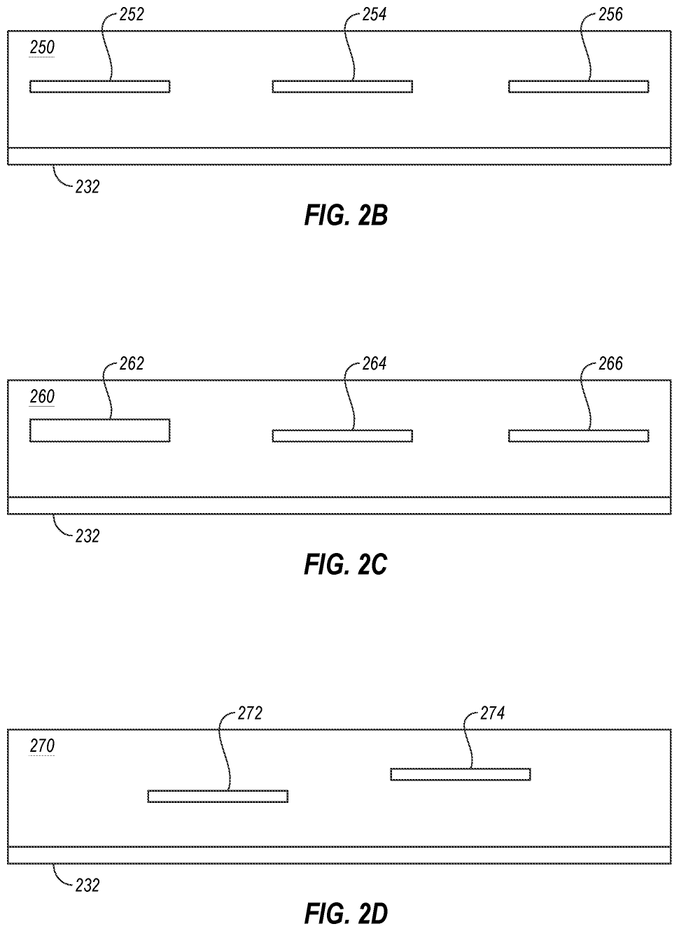

FIG. 2A illustrates a perspective view of a reconfigurable mainframe 200, in accordance with an embodiment of the present disclosure. The reconfigurable mainframe 200 may correspond to mainframe 104 of FIGS. 1A-C in an embodiment.

Reconfigurable mainframe 200 includes a base 206 (also referred to as a floor) on which a set of frames are mounted. Each frame may correspond to and frame a side or facet of the mainframe 200. The set of frames may conceptually be a single three dimensional frame 201 having multiple frame faces, where each of the frame faces frames a facet of the mainframe 200. The frame 201 may include columns 204A-D, and may further include beams 208A-D connecting the columns 204A-D. Each of the frames (or frame faces) may comprise a portion of the base, a pair of columns and a corresponding beam that connects the pair of columns. For example, base 206, columns 204B-C and beam 208A may make up a first frame (or frame face) for a first facet, base 206, columns 204A-B and beam 208B may make up a second frame (or frame face) for a second facet, base 206, columns 204A and 204D and beam 208C may make up a third frame (or frame face) for a third facet, and base 206, columns 204C-D and beam 208D may make up a fourth frame (or frame face) for a fourth facet.

Each of the frames (or frame faces) may include a lip 210A, 210B in the base 206. The lip 210A-B may be configured to support forces transferred to the lip 210A-B by a replaceable interface plate attached to a facet. Additionally, each of the frames (or frame faces) may include a groove or other feature that accepts an o-ring 215, 220. The o-ring may seal a replaceable interface plate to the frame (or frame face).

As illustrated, a replaceable interface plate 230 attaches to a frame (or frame face) of a facet of the mainframe 200. The replaceable interface plate 230 may be attached to the frame via bolts, screws, and/or other attachment mechanisms. The replaceable interface plate 230 may include a configured number, size and location of openings and receiving areas 234, 236 for attaching replaceable chamber ports, each of which may be configured to provide access for a robot arm to a process chamber. Each attached replaceable chamber port may include one or more slit valves (not shown), LCFs (not shown) and/or other components attached thereto or integrated therein.

The replaceable interface plate 230 may be a metal plate. For example, the replaceable interface plate may be formed from aluminum, an aluminum alloy, steel, or another metal. In some embodiments, the replaceable interface plate includes a surface treatment, such as a coating or anodization layer (e.g., an Al₂O₃ anodization layer). Examples of coatings include coatings deposited by chemical vapor deposition (CVD), atomic layer deposition (ALD), electroplating, and so on. Some example coatings include dielectric coatings, Al₂O₃ coatings, nickel plating, Y₂O₃ coatings, and so on. The replaceable interface plate 230 may be coated prior to attachment to the mainframe 200. Alternatively, the mainframe 200 may be coated after replaceable interface plates have been attached. Accordingly, in some embodiments portions of the replaceable interface plate 230 have the surface treatment.

The replaceable interface plate 230 additionally includes a step 232 on an interior bottom surface of the replaceable interface plate 230 in some embodiments. The step may mate with a lip on a sidewall of the base 206 that forms a frame (or frame face) to which the replaceable interface plate 230 is mounted. In some embodiments, the base 206 extends beyond the frame and a bottom of replaceable interface plate 230 may rest on the base 206 for load transfer.

The mainframe is configured to operate under vacuum, which can cause large vertical and horizontal forces to be applied to the mainframe 200 based on a pressure difference between the interior volume of the mainframe and an exterior of the mainframe (e.g., which may be at atmospheric pressure). The frame 201, if exposed to the forces, may bend and/or buckle. Accordingly, in embodiments the replaceable interface plates (e.g., replaceable interface plate 230) are designed to be load bearing for the mainframe 200, and the frame of the first facet is not load bearing of forces caused by vacuum. Thus, the replaceable interface plate 230 bears vertical forces on the mainframe 200 caused by differences in pressure between the interior volume of the mainframe and an exterior of the mainframe. These vertical forces may be transferred from an integrated lid (not shown) to the replaceable interface plate 230, and to the base at an interface of the step 232 and the lip of the base that is mated with the step 232 (or another interface of the replaceable interface plate 230 and base 206).

In one embodiment, a vertical force of approximately 95,000 pounds of pressure is applied to the mainframe 200 when it is under vacuum. In an embodiment in which two facets have lengths of about 100-150 inches, and two facets have lengths of about 40-60 inches, about 30-40% of the vertical force is supported by each of the replaceable interface plates attached to long facets, and about 10-15% of the force is supported by each of the replaceable interface plates attached to short facets. Accordingly, a single replaceable interface plate may be configured to bear a force of about 28,500 to 38,000 pounds of force without flexing.

In an alternative embodiment, a step and lip are not used to transfer vertical forces from one or more of the replaceable interface plates to the base 206. Rather than a mated step and lip, the replaceable interface plate 230 may include pins on an interior bottom surface of the replaceable interface plate. The pins may be, for example, square or round pins, and may be periodically spaced. The plurality of pins may mate with one or more features in a sidewall of the base, and the vertical forces may be transferred from the replaceable interface plate to the base at an interface of the plurality of pins and the one or more features. The features may be, for example, holes, a lip, or other features that mate with the pins.

In an alternative embodiment, the base extends out beneath the replaceable interface plates, and vertical forces may be transferred from the replaceable interface plates to the base without the use of any steps, lips, pins or other features in the base or replaceable interface plates.

Though not shown, additional replaceable interface plates may be attached to the remaining facets of the mainframe 200. Additionally, an integrated lid may be formed at a top of the mainframe over the frame 201 and over the replaceable interface plates. In embodiments, the integrated lid includes a first plurality of load transfer features that contact a second plurality of load transfer features on the replaceable interface plates. In one embodiment, the first plurality of load transfer features are set screws that extend vertically downward from the lid toward the replaceable interface plates, and the second plurality of load transfer features are inserts or attachments on a top surface of the replaceable interface plates. The replaceable interface plates may be made of a relatively soft metal, such as aluminum, and the second plurality of load transfer features may be made of a harder metal such as steel. Accordingly, the first plurality of load transfer features would damage the replaceable interface plate if they engaged directly with the material that the replaceable interface plate is made of. However, the first plurality of load transfer features do not damage the second plurality of load transfer features in the top surface of the replaceable interface plate.

FIG. 2B illustrates a side view of a first example replaceable interface plate 250, in accordance with an embodiment of the present disclosure. The first replaceable interface plate 250 includes a step 232 and three openings 252, 254, 256 that all have the same width, height and vertical position.

FIG. 2C illustrates a side view of a second example replaceable interface plate 260, in accordance with an embodiment of the present disclosure. The second replaceable interface plate 260 includes a step 232 and three openings 262, 264, 266 that have varying widths and heights.

FIG. 2D illustrates a side view of a third example replaceable interface plate 270, in accordance with an embodiment of the present disclosure. The third replaceable interface plate 270 includes a step 232 and two openings 272, 274 that have equal widths and heights, but different vertical position.

Any of the first example replaceable interface plate 250, second example replaceable interface plate 260 or third example replaceable interface plate 270 may be attached to the mainframe 200 in embodiments.

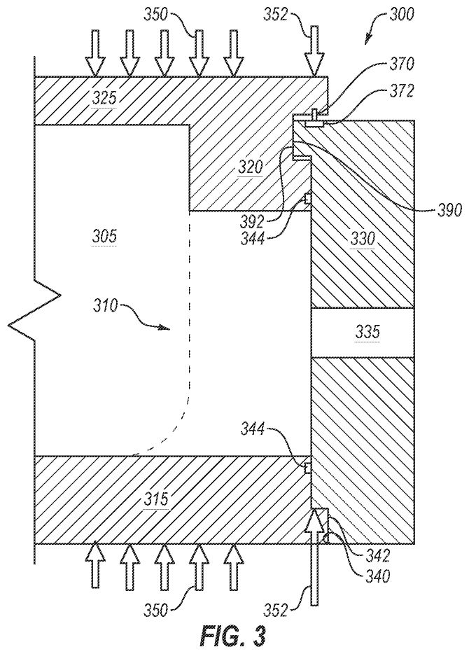

FIG. 3 depicts a cross sectional side view of a mainframe 300 and an attached replaceable interface plate 330, taken at a location of an opening 335 machined into the replaceable interface plate 330, in accordance with an embodiment of the present disclosure. The mainframe 300 includes a base 315, a frame face (comprising a beam 320, multiple columns (not shown) and a portion of the base), and an integrated lid 325 that is attached to and/or part of a frame comprising the beam 320, base 315 and columns (not shown). The frame may include beam 320, base 315 and columns for one or more facet 310 of the mainframe 300. The replaceable interface plate 330 is attached to the frame that frames the facet 310 of the mainframe 300.

The base 315 includes a lip 340 on a sidewall of the base 315. The replaceable interface plate 330 includes a step 342 on an interior bottom surface of the replaceable interface plate 330, wherein the step 342 mates with the lip 340 on the sidewall of the base 315. As previously described, forces 350 may be applied to the mainframe 300 when an interior volume 305 of the mainframe 300 is pumped down to vacuum. These forces may be a concentrated force 352 that the replaceable interface plate 330 bears. As shown, first load transfer features 370 of the lid engage with second load transfer features 372 of the replaceable interface plate. In one embodiment, the first load transfer features 370 and second load transfer features 372 are composed of a harder material than a remainder of the lid and/or replaceable interface plate. Accordingly, the first load transfer features 370 and second load transfer features 372 may engage with considerable force without deforming or damaging either the integrated lid 325 or the replaceable interface plate 330. The force may be transferred from the integrated lid 325, through the replaceable interface plate 330, and to the lip 352 of the base 315.

The frame for the facet to which the replaceable interface plate 330 attaches (e.g., including beam 320, columns (not shown) and sidewall of the base) may each include a notch or groove 344 into which an o-ring may be inserted to ensure a seal between the replaceable interface plate 330 and the frame.

In one embodiment, the replaceable interface plate 330 includes a lip 390 at a top of an interior surface of the replaceable interface plate 330. The beam 320 may include a corresponding step 392 that may mate with the lip 390. Notably, a top of the step 392 does not contact a bottom of the lip 390. In other embodiments, the replaceable interface plate 330 does not include a lip, and the beam 320 does not include a step.

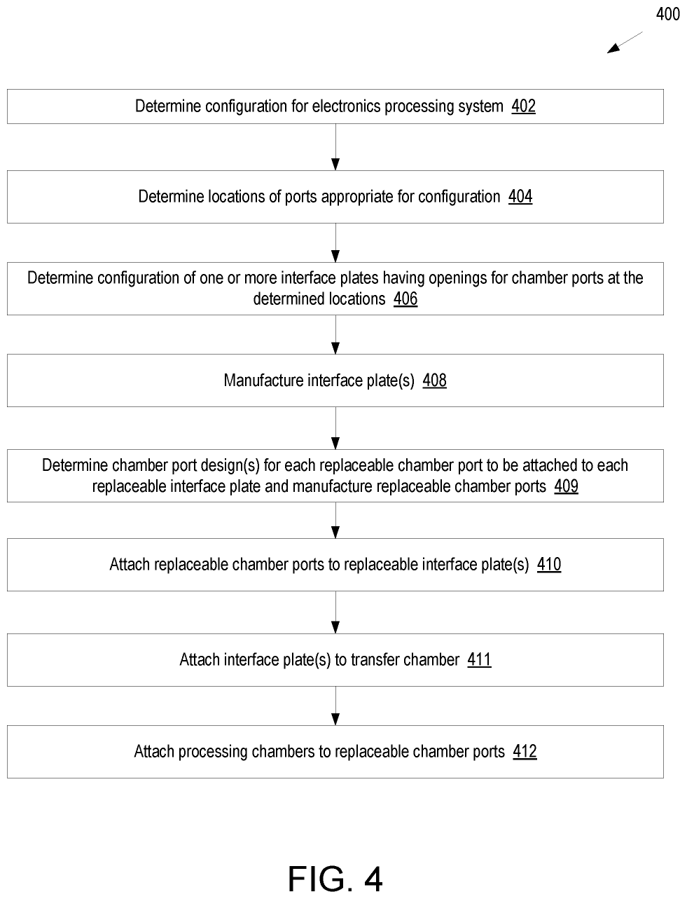

FIG. 4 illustrates a method 400 for assembling a reconfigurable mainframe of an electronic device manufacturing system, in accordance with an embodiment of the present disclosure. Some operations of method 400 may be performed by processing logic, which may execute on a computing device such as a general purpose computer. For example, some operations may be performed using computer aided drafting and/or computer aided manufacturing (CAM) software installed on a computer.

At block 402 of method 400, a mainframe configuration is determined, including making a determination of a first plurality of process chambers to be coupled to a first facet of a mainframe. Additionally, determinations may be made of load locks and/or process chambers to be connected to one or more other facets of the mainframe.

At block 404, a determination may be made of locations of chamber ports appropriate for the determined mainframe configuration (e.g., that will accommodate access to each of the process chambers and/or load locks). At block 406, configurations of one or more replaceable interface plates are determined. The replaceable interface plates may be configured to have openings and/or receiving areas for attaching replaceable chamber ports at each of the determined locations. At block 408, the replaceable interface plates may be manufactured. This may include machining a metal (e.g., aluminum) and/or applying a surface treatment to at least a portion of the replaceable interface plates.

At block 409, chamber port designs are determined for each of the receiving areas of the replaceable interface plates. Replaceable chamber ports are manufactured according to the determined chamber port designs. At block 410, the replaceable chamber ports are mounted to the replaceable interface plates. This may include bolting or screwing the replaceable chamber ports to the replaceable interface plates at the receiving areas.

At block 411, the replaceable interface plates are attached to the mainframe (transfer chamber). This may include bolting or screwing the replaceable interface plates to the frames of the appropriate facets of the mainframe. At block 412, the determined process chambers and/or load locks may then be attached to the appropriate replaceable chamber ports as per the determined configuration.

At any time an engineer may determine a new configuration for the mainframe. At such a time, the method 400 may be repeated. For example, a determination of a second plurality of process chambers to be coupled to the first facet of the mainframe may be made, new locations of a second plurality of chamber ports on the facet that will accommodate the second plurality of process chambers may be determined, a configuration of a second replaceable interface plate having receiving areas for one of the second plurality of replaceable chamber ports at each of the new locations may be determined, and the second replaceable interface plate may be manufactured. If the locations of chamber ports is not to change, than a same replaceable interface plate may be used, but one or more replaceable chamber ports may be removed from the replaceable interface plate and replaced with a different chamber port.

The second replaceable interface plate may have at least one of a) a different number of receiving areas for chamber ports than the first replaceable interface plate, b) different locations of one or more chamber ports as compared to the plurality of chamber ports in the first replaceable interface plate, c) different sizes of one or more receiving areas for replaceable chamber ports as compared to the plurality of receiving areas for chamber ports in the first replaceable interface plate, and so on.

A new replaceable chamber port may differ from a previously used replaceable chamber port by, for example, a type of slit valve used, a type of local center finder used, and so on.

Prior to block 410, the existing process chambers may be removed from chamber ports attached to the first replaceable interface plate, followed by removal of the first replaceable chamber ports from the first replaceable interface plate. Alternatively, prior to block 411, the existing process chambers may be removed from the chamber ports attached to the first replaceable interface plate, and the first replaceable interface plate may be removed from the mainframe. Subsequently, the operations of blocks 410 and/or 411 may be performed, causing the mainframe to have an entirely new configuration (e.g., with different numbers of chamber ports, different positions of chamber ports, different numbers and/or types of process chambers, different types of chamber ports, and so on).

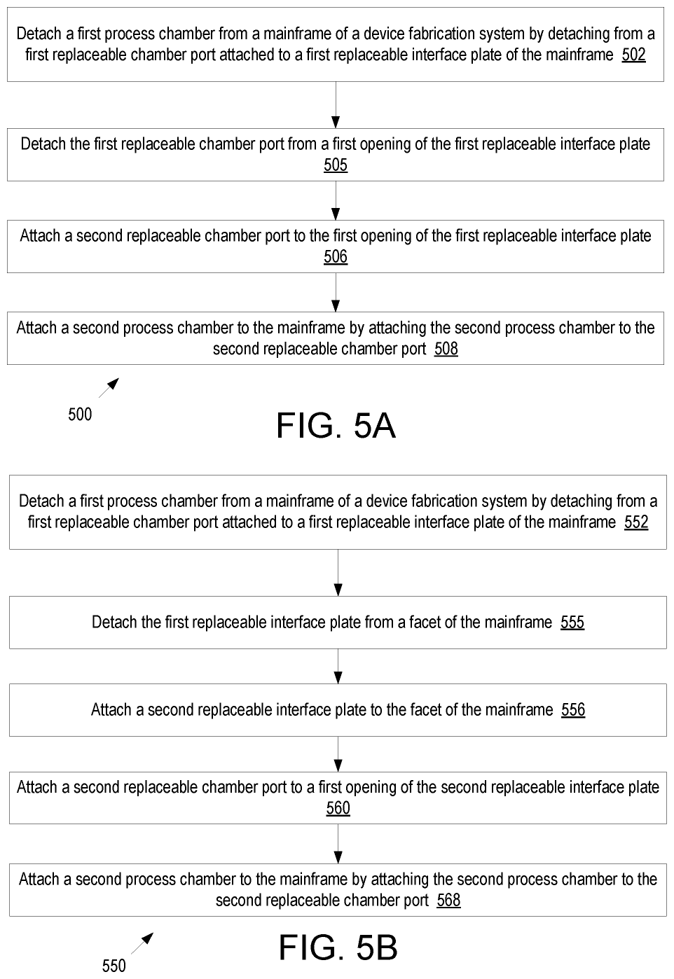

FIG. 5A illustrates a first method 500 for replacing a process chamber of a mainframe, in accordance with an embodiment of the present disclosure. The first method 500 may be performed to update a mainframe configuration when a size and/or location of a chamber port is the same for an original process chamber attached to the mainframe and a new process chamber that is to replace the original process chamber.

At block 502 of method 500, a first process chamber is detached from a mainframe of a device fabrication system. The mainframe includes a base, a plurality of facets on the base, and a first replaceable interface plate attached to a first frame of a first facet of the plurality of facets. The first replaceable interface plate comprises a plurality of replaceable chamber ports. Detaching the first process chamber from the mainframe comprises detaching the first process chamber from a first replaceable chamber port coupled to the first replaceable interface plate.

At block 505, the method includes detaching the first replaceable chamber port from a first opening of the first replaceable interface plate, wherein the first replaceable chamber port is configured to couple to the first process chamber.

At block 506, the method includes attaching a second replaceable chamber port to the first opening of the first replaceable interface plate, wherein the second replaceable chamber port is configured to couple to a second process chamber different from the first process chamber.

At block 508, the method includes attaching the second process chamber to the mainframe by attaching the second process chamber to the second replaceable chamber port. The second process chamber may have a different shaped area for connecting to a chamber port, and may not properly engage with the first chamber port. However, because replaceable interface plate includes replaceable chamber ports, the first chamber port may be swapped out with the second chamber port to accommodate the different shape of the second process chamber.

FIG. 5B illustrates a second method 550 for replacing a process chamber of a mainframe, in accordance with an embodiment of the present disclosure. The second method 550 may be performed to update a mainframe configuration when a size and/or location of a chamber port is different between an original process chamber attached to the mainframe and a new process chamber that is to replace the original process chamber. For example, if a new process chamber has a port at a different height or a different horizontal position as compared to an original process chamber attached to a mainframe, then method 550 may be performed.

At block 552 of method 550, the method includes detaching a first process chamber from a mainframe of a device fabrication system. The mainframe includes a base, a plurality of facets on the base, and a first replaceable interface plate attached to a first frame of a first facet of the plurality of facets. The first replaceable interface plate comprises a plurality of replaceable chamber ports. Detaching the first process chamber from the mainframe comprises detaching the first process chamber from a first replaceable chamber port coupled to the first replaceable interface plate.

At block 555, the method includes detaching the first replaceable interface plate from the first frame of the mainframe.

At block 556, the method includes attaching a second replaceable interface plate to the first frame of the mainframe, wherein the second replaceable interface plate has a second opening that is different from the first opening.

At block 560, the method includes attaching a second replaceable chamber port to the second opening of the second replaceable interface plate, wherein the second replaceable chamber port is configured to couple to a second process chamber different from the first process chamber.

At block 568, the method includes attaching a second process chamber to the mainframe by attaching the second process chamber to the second replaceable chamber port. The second process chamber may have a port at a different location than the first process chamber. Accordingly, attaching the second process chamber to the mainframe may not be accomplished using the first replaceable interface plate. Accordingly, the second replaceable interface plate may be manufactured and attached to the mainframe, where the second replaceable interface plate may have an opening at a new location that is appropriate for the second process chamber.

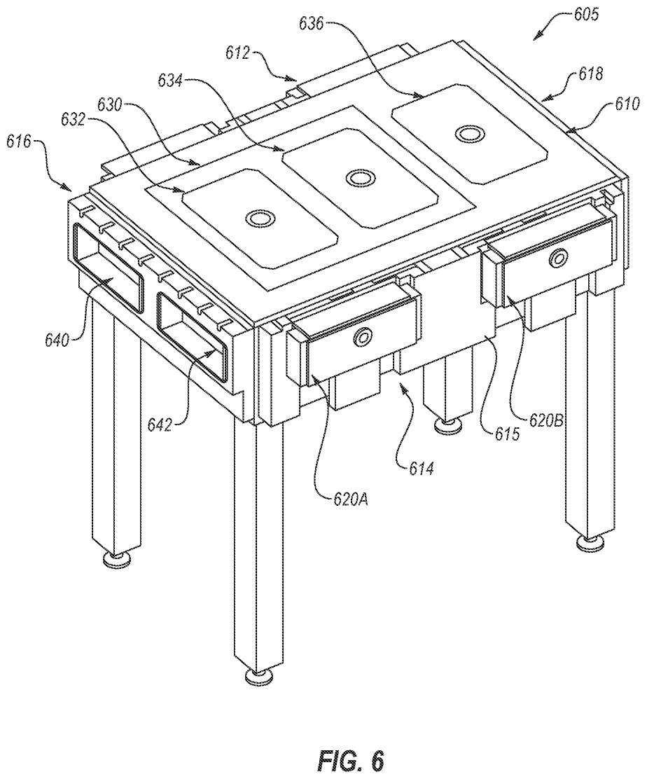

FIG. 6 illustrates a schematic isometric view of a reconfigurable mainframe 605 for an electronic device manufacturing system, in accordance with an embodiment of the present disclosure. The reconfigurable mainframe 605 includes a frame (not shown) having four side facets (e.g., one for each side of the frame). An integrated lid 610 is disposed over the frame. The integrated lid 610 includes one or more access panels 630, 632, 634, 636 that can be opened to gain access to an interior of the reconfigurable mainframe 605. In one embodiment, a larger access panel 630 includes one or more smaller sub-access panels 632, 634.

Each facet of the reconfigurable mainframe 605 includes an attached replaceable interface plate 612, 614, 616, 618. Replaceable interface plate 618 has no openings, and is not configured to receive any chamber ports. Replaceable interface plate 616 has two integrated chamber ports 640, 642, and may be configured for coupling to load lock chambers in an embodiment. Replaceable interface plates 612, 614 each include two attached replaceable chamber ports 620. Replaceable interface plate 614 as shown includes a plate body 615 and attached replaceable chamber ports 620.

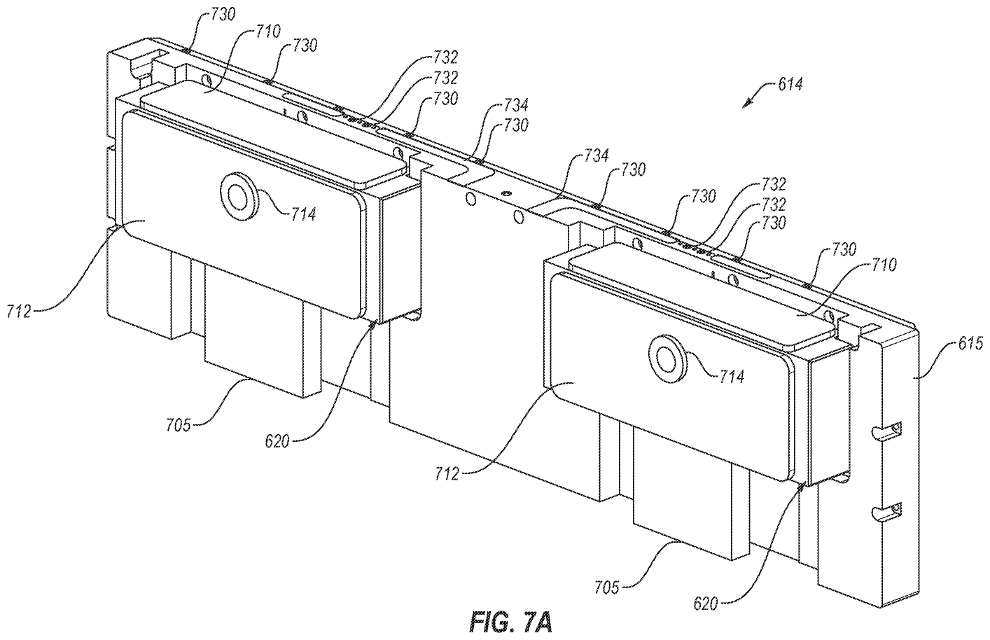

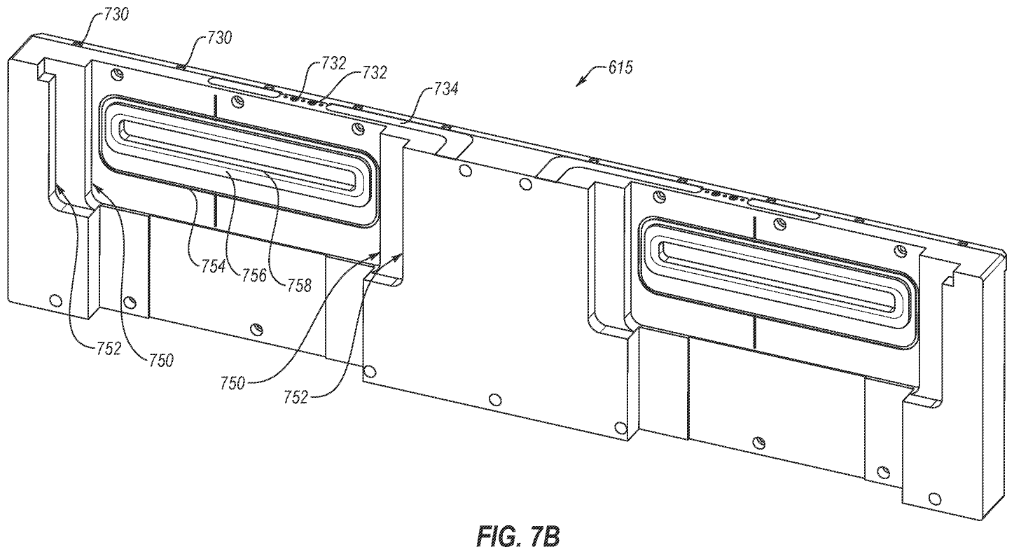

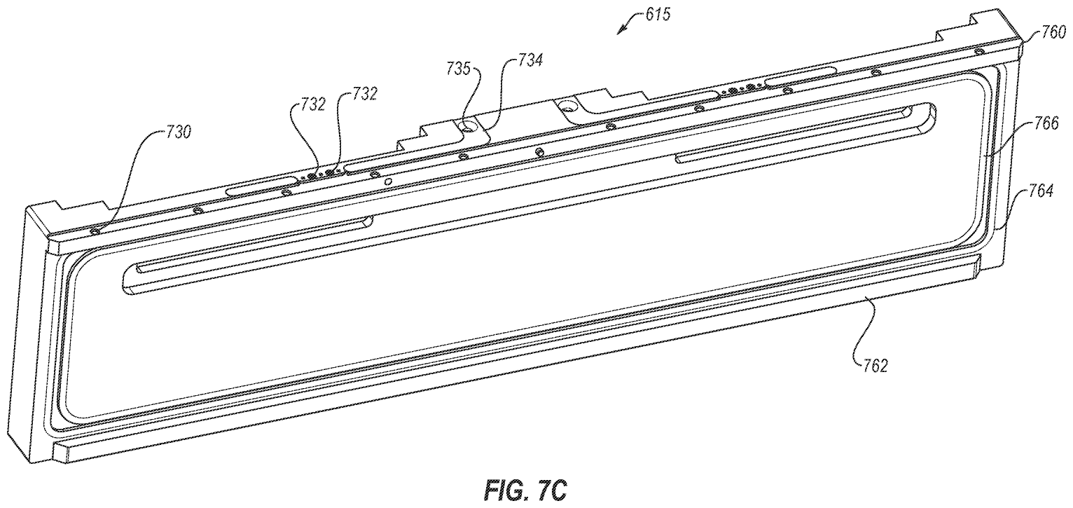

FIG. 7A illustrates a replaceable interface plate assembly 614 with replaceable chamber ports 620 for a reconfigurable mainframe of an electronic device manufacturing system, in accordance with an embodiment of the present disclosure. In particular, FIG. 7A illustrates a chamber side of a replaceable interface plate assembly 614. As shown, two replaceable chamber ports 620 are attached to receiving areas formed in a body of the replaceable interface plate 615. Each replaceable chamber port 620 includes a chamber port body to which a top plate 710 is mounted. Each replaceable chamber port 620 further includes one or more arm 705 that extends vertically below the chamber port body. Each arm 705 may move vertically to open or close a slit valve of the replaceable chamber port 620.

The replaceable interface plate 615 includes a plurality of load transfer features 730 along a length of a top surface of the replaceable interface plate 615. Each of the load transfer features may be a disc, plate, or other object that is formed of a material that has a higher hardness than a material of a body of the replaceable interface plate 615. For example, the body of the replaceable interface plate 615 may be made of aluminum, and the load transfer features 730 may be made of steel or iron. In one embodiment, the replaceable interface plate body 615 includes a plurality of threaded holes (e.g., that are not through holes), each of which receives a threaded insert. Each threaded insert may be a load transfer feature, and may be configured to contact a load transfer feature (e.g., a set screw) on an integrated lid of a reconfigurable mainframe.

A lid, replaceable interface plate 615 and/or base of a mainframe may include one or more LCF devices or components. The local center finders are each configured to determine a center of an object (e.g., a ring, wafer, substrate, etc.) passing through an associated chamber port 620 (e.g., which may include a slit value). LCFs may include an arrangement of laser and detector pairs. Each laser may project a laser beam, which may be received by a corresponding detector in a laser and detector pair. In embodiments, the lasers direct the laser beams vertically or at an angle relative to vertical. Each detector is positioned in the path of a laser beam from a corresponding laser. When a substrate (e.g., a wafer) is passed through the chamber port 620, it blocks the laser beams such that the laser beams are not received by the detectors. Based on known information about a size and shape of the substrate passing through the chamber port 620, known information about positions of the lasers and detectors, and known information about respective positions of a transfer chamber robot at which each of the respective detectors stopped receiving a laser beam, a center of the substrate may be determined. Other types of LCFs may also be used, such as camera-based local center finders and/or runout ribbon-based local center finders.

In some embodiments, a base of a mainframe includes one or more lasers that emit laser beams, and a lid of the mainframe includes one or more laser detectors that receive the laser beams unless an object passes between the laser source(s) and the laser detector(s). In some embodiments, a base of the mainframe includes one or more lasers, and replaceable interface plate 615 includes one or more laser detectors. In some embodiments, a base of the mainframe includes the laser(s) and the detectors, and optics (e.g., fiber optics) in the replaceable interface plate 615 guides light beams from the lasers and/or to the detectors. In some embodiments, the lasers and detectors are integrated into the chamber ports 620. In some embodiments, the lasers and detectors are integrated into the replaceable interface plate 615. In some embodiments, the lasers and detectors are integrated into the lid of the mainframe, and optics (e.g., fiber optics) in the replaceable interface plate 615 guides light beams from the lasers and/or to the detectors.

In one embodiment, the replaceable interface plate body 615 includes one or more (e.g., a plurality of) through holes 732 through which local center finder (LCF) beams (e.g., laser beams) are directed. The through holes may be configured to pass a laser beam from a laser of a local center finder (LCF) across the replaceable chamber port 620 and to a detector of the LCF. When a substrate passes through a chamber port, an LCF beam may be broken or interrupted, and a detector may detect a substrate. In one embodiment, LCF devices (e.g., laser source and/or detector) are integrated into and/or attached to the replaceable interface plate. In one embodiment, LCF devices are integrated into a lid of the mainframe. In one embodiment, replaceable interface plate body 615 includes a channel 734 that receives a fiber optic cable that can guide one of more LCF beams so that they cross the chamber port 620. Accordingly, the replaceable interface plate 615 may include one or more fiber optic cables disposed therein that are configured to guide a laser beam from a laser of a local center finder (LCF) to and across the chamber port 620 and/or from the chamber port to a detector of the LCF.

FIG. 7B illustrates a chamber side of the replaceable interface plate of FIG. 7A with the replaceable chamber ports removed, in accordance with an embodiment of the present disclosure. As shown, replaceable interface plate body 615 includes a pair of chamber port receiving areas, each of which includes an opening 758 through which substrates may pass. Additionally, each chamber port receiving area includes inner cutouts 750 and outer cutouts 752. Inner cutouts 750 and outer cutouts 752 are shaped to mate with chamber ports in embodiments. In embodiments, replaceable interface plate body 615 includes an o-ring groove 754 for receiving an o-ring to seal against a replaceable chamber port and an oval-shaped polished surface 756 that is concentric with the o-ring groove 754. The oval-shaped polished surface 756 may have a very low roughness to increase a contact area and improve a seal with the replaceable chamber port 620.

FIG. 7C illustrates a mainframe side of the replaceable interface plate of FIG. 7A with the replaceable chamber ports removed, in accordance with an embodiment of the present disclosure. As shown, the channel 734 may include a through hole at one end to enable a fiber-optic cable to run vertically through the replaceable interface plate so that it can shine LCF beams through one or more LCF holes 732. Mainframe side of interface plate body 615 (also referred to as a replaceable interface plate) includes a lip 760 at a top of the replaceable interface plate 615 that extends towards the mainframe and that includes the load transfer features 730. The mainframe side of replaceable interface plate 615 further includes a lip 762 at a bottom of the replaceable interface plate that extends towards the mainframe, and that is configured to contact a floor or receiving area of the mainframe. The mainframe side of replaceable interface plate 615 may further include an o-ring groove 764 for receiving an o-ring and/or a gasket groove 766 for receiving a radio-frequency (RF) gasket for sealing against a mainframe.

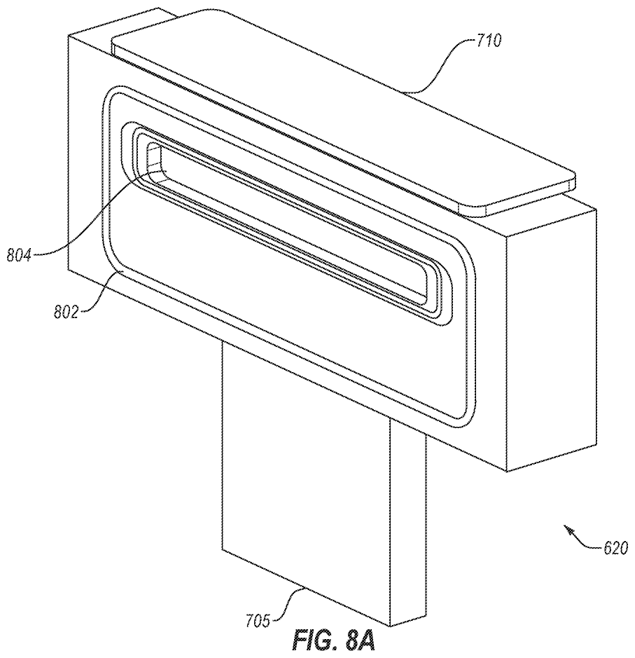

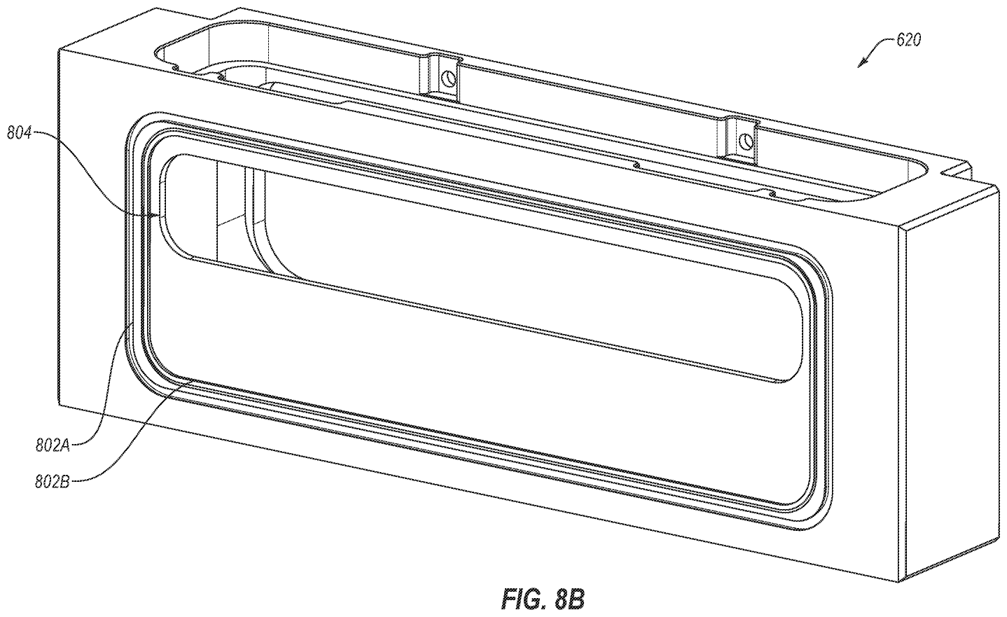

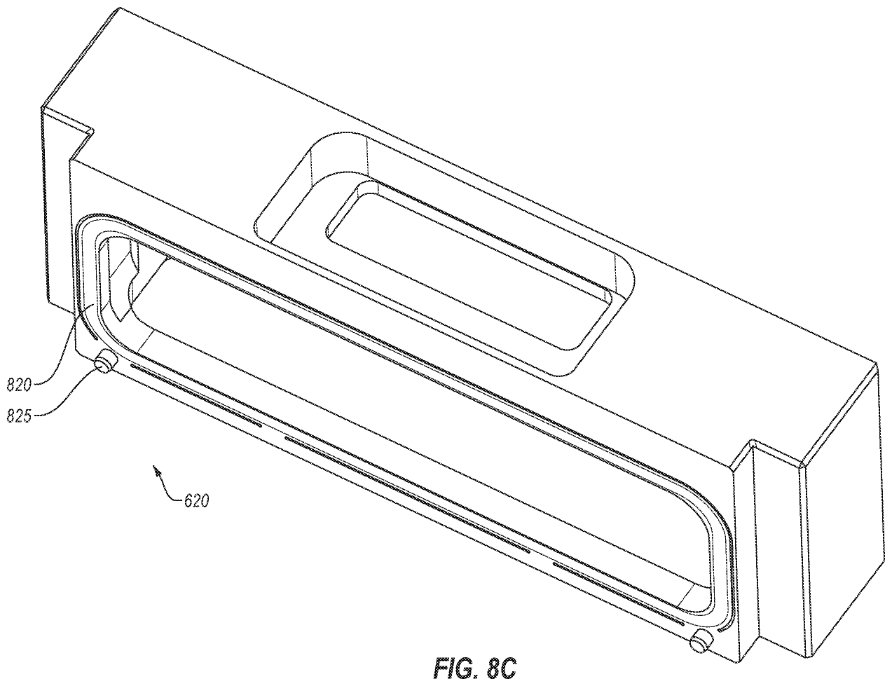

FIG. 8A illustrates a replaceable chamber port 620 for a replaceable interface plate, in accordance with an embodiment of the present disclosure. As shown, the replaceable chamber port 620 includes one or more arm 705 that extends vertically below the chamber port 620. The arm 705 may move vertically to open or close a slit valve of the replaceable chamber port 620. The replaceable chamber port further includes a top plate 710 that may be removably fastened to a top of the chamber port 620. The top plate 710 may be removed to provide access to an interior of the chamber port 620, such as for maintenance. In embodiments, the chamber port 620 further includes an opening 804 for a slit valve and a groove 802 for receiving an o-ring for sealing against a process chamber.

FIG. 8B illustrates top isometric view of a body of the replaceable chamber port of FIG. 8A with the arm 705 and top plate 710 removed, in accordance with an embodiment of the present disclosure. In particular, FIG. 8B shows a process chamber side of a replaceable chamber port 620. In one embodiment, replaceable chamber port 620 includes dual o-ring grooves, each configured to receive an o-ring that is to seal against a process chamber. In embodiments, the dual o-ring grooves are concentric and enable differential pumping.

A region between the o-ring grooves 802A, 802B may be an intermediate vacuum region. The chamber port 620 may include one or more channels (i.e. holes) that fluidly couple the intermediate vacuum regions to a vacuum port. Differential pumping may be performed to pump the intermediate vacuum region to a pressure that is between a pressure of the interior volume of the mainframe and atmospheric pressure. A first o-ring may be disposed in groove 802A of the chamber port 620, wherein an exterior surface of the first o-ring is exposed to an external environment, and wherein an interior surface of the first o-ring is exposed to the intermediate vacuum region. A second o-ring may be disposed in groove 802B of the chamber port 620, wherein an exterior surface of the second o-ring is exposed to the intermediate vacuum region, and wherein an interior surface of the second o-ring is exposed to the interior volume of the mainframe. The external environment may have a first pressure, the intermediate vacuum region may maintain a second pressure that is lower than the first pressure, and the interior volume may maintain a third pressure that is lower than the second pressure.

FIG. 8C illustrates bottom isometric view of a mainframe side of a body of the replaceable chamber port 620 of FIG. 8A, in accordance with an embodiment of the present disclosure. As shown, replaceable chamber port 620 may include an oval-shaped surface 820 that is to interface with one or more o-rings on a replaceable interface plate. Additionally, chamber port 620 includes one or more registration features (e.g., a pair of registration features) 825 for registering placement of the chamber port 620 against a replaceable interface plate. The registration features 825 may be configured to mate with registration features on a replaceable interface plate in embodiments. For example, registration features 825 may include cylindrical projections that may mate with cylindrical holes in a replaceable interface plate.

In the foregoing description, numerous specific details are set forth, such as specific materials, dimensions, processes parameters, etc., to provide a thorough understanding of the present disclosure. The particular features, structures, materials, or characteristics may be combined in any suitable manner in one or more embodiments. The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is simply intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. Reference throughout this specification to “an embodiment”, “certain embodiments”, or “one embodiment” means that a particular feature, structure, or characteristic described in connection with the embodiment is included in at least one embodiment. Thus, the appearances of the phrase “an embodiment”, “certain embodiments”, or “one embodiment” in various places throughout this specification are not necessarily all referring to the same embodiment.

The present disclosure has been described with reference to specific exemplary embodiments thereof. The specification and drawings are, accordingly, to be regarded in an illustrative rather than a restrictive sense. Various modifications of the disclosure in addition to those shown and described herein will become apparent to those skilled in the art and are intended to fall within the scope of the appended claims.

We claim:

1. A mainframe of a device fabrication system, comprising:
a base;
a plurality of facets on the base, wherein a first facet of the plurality of facets comprises a first frame;
a lid over the plurality of facets, wherein the base, the lid and the plurality of facets together define an interior volume;
one or more robot arms in the interior volume; and
a first replaceable interface plate attached to the first frame of the first facet, the first replaceable interface plate comprising a plurality of replaceable chamber ports, wherein:
a first replaceable chamber port of the plurality of replaceable chamber ports is configured to couple to, and provide access for the robot arm to, a first process chamber; and
a second replaceable chamber port of the plurality of replaceable chamber ports is configured to couple to, and provide access for the robot arm to, a second process chamber.

2. The mainframe of claim 1, further comprising:
a first plurality of weight transfer features protruding from the lid; and
a second plurality of weight transfer features disposed on a top face of the first replaceable interface plate, wherein the first plurality of weight transfer features are to interface with the second plurality of weight transfer features to transfer a load from the lid to the first replaceable interface plate.

3. The mainframe of claim 2, wherein the first plurality of weight transfer features comprise a first plurality of set screws that extend vertically downward from the lid towards the first replaceable interface plate.

4. The mainframe of claim 3, wherein the first replaceable interface plate is composed of a first material having a first hardness, and wherein the second plurality of weight transfer features comprise a plurality of features composed of a second material having a second hardness that is higher than the first hardness.

5. The mainframe of claim 4, wherein the plurality of features comprise a plurality of discs.

6. The mainframe of claim 4, wherein the first replaceable interface plate comprises aluminum, and wherein the first plurality of weight transfer features and the second plurality of weight transfer features comprise at least one of steel or iron.

7. The mainframe of claim 1, wherein the lid is integrated with the mainframe such that the lid is not removeable from the plurality of facets.

8. The mainframe of claim 7, wherein the integrated lid comprises a plurality of access plates that are openable to provide access to the interior volume.

9. The mainframe of claim 1, wherein the first replaceable chamber port has a first configuration suitable for coupling to the first process chamber, and wherein the second replaceable chamber port has a second configuration, different from the first configuration, suitable for coupling to the second process chamber.

10. The mainframe of claim 1, further comprising:
at least one of a laser or a detector of a local center finder integrated into the lid, wherein the local center finder is configured to detect a center of a substrate that passes through the first replaceable chamber port.

11. The mainframe of claim 1, wherein the one or more robot arms comprise a first robot arm and a second robot arm.

12. The mainframe of claim 1, wherein the first replaceable interface plate comprises one or more through holes that are configured to pass a laser beam from a laser of a local center finder (LCF) across the first replaceable chamber port and to a detector of the LCF.

13. The mainframe of claim 1, wherein the first replaceable interface plate comprises one or more fiber optic cables disposed therein that are configured to guide a laser beam at least one of a) from a laser of a local center finder (LCF) to the first replaceable chamber port or b) from the first replaceable chamber port to a detector of the LCF.

14. A replaceable interface plate for attachment to a facet of a mainframe, the replaceable interface plate comprising:
a plurality of openings, each opening of the plurality of openings configured to receive a replaceable chamber port;
a first replaceable chamber port coupled to the replaceable interface plate at a first opening of the plurality of openings, wherein the first replaceable chamber port is configured to couple to a first process chamber; and
a second replaceable chamber port coupled to the replaceable interface plate at a second opening of the plurality of openings, wherein the second replaceable chamber port is configured to couple to a second process chamber.

15. The replaceable interface plate of claim 14, wherein the replaceable interface plate is configured to bear vertical forces on the mainframe caused by differences in pressure between an interior volume of the mainframe and an exterior of the mainframe.

16. The replaceable interface plate of claim 14, wherein the first replaceable chamber port has a first configuration suitable for coupling to the first process chamber, and wherein the second replaceable chamber port has a second configuration, different from the first configuration, suitable for coupling to the second process chamber.

17. The replaceable interface plate of claim 14, wherein at least one of the first replaceable chamber port or the second replaceable chamber port is a dual gate chamber port.

18. The replaceable interface plate of claim 14, further comprising at least one of:
one or more through holes that are configured to pass a laser beam from a laser of a local center finder (LCF) across the first replaceable chamber port and to a detector of the LCF; or
one or more fiber optic cables disposed therein that are configured to guide a laser beam at least one of a) from a laser of a local center finder (LCF) to the first replaceable chamber port or b) from the first replaceable chamber port to a detector of the LCF.

19. A method comprising:
detaching a first process chamber from a mainframe of a device fabrication system comprising a base, a plurality of facets on the base, and a first replaceable interface plate attached to a first frame of a first facet of the plurality of facets, the first replaceable interface plate comprising a plurality of replaceable chamber ports, wherein detaching the first process chamber from the mainframe comprises detaching the first process chamber from a first replaceable chamber port coupled to the first replaceable interface plate;
detaching the first replaceable chamber port from a first opening of the first replaceable interface plate, wherein the first replaceable chamber port is configured to couple to the first process chamber;
attaching a second replaceable chamber port to the first opening of the first replaceable interface plate, wherein the second replaceable chamber port is configured to couple to a second process chamber different from the first process chamber; and
attaching the second process chamber to the mainframe by attaching the second process chamber to the second replaceable chamber port.

20. The method of claim 19, further comprising:
detaching the second process chamber from the mainframe of the device fabrication system, wherein detaching the second process chamber from the mainframe comprises detaching the second process chamber from a second replaceable chamber port coupled to the first replaceable interface plate;
detaching the first replaceable interface plate from the first frame of the mainframe;
attaching a second replaceable interface plate to the first frame of the mainframe, wherein the second replaceable interface plate has a second opening that is different from the first opening;
attaching a third replaceable chamber port to the second opening of the second replaceable interface plate, wherein the third replaceable chamber port is configured to couple to a third process chamber different from the first process chamber and the second process chamber; and
attaching the third process chamber to the third replaceable chamber port.
